(19) United States
(12) Patent Application Publication
(10) Pub. No.: US 2023/0139947 A1
(43) Pub. Date: May 4, 2023

(54) POLISHING METHOD, POLISHING APPARATUS, AND COMPUTER-READABLE STORAGE MEDIUM STORING PROGRAM

(71) Applicant: EBARA CORPORATION, Tokyo (JP)

(72) Inventors: Ban ITO, Tokyo (JP); Takeshi IIZUMI, Tokyo (JP); Gael ROYERE, Tokyo (JP); Patrick ONG, Leuven (BE); Kevin VANDERSMISSEN, Leuven (BE); Katia DEVRIENDT, Leuven (BE)

(21) Appl. No.: 17/909,966

(22) PCT Filed: Feb. 2, 2021
(86) PCT No.: PCT/JP2021/003691

§ 371 Date: Sep. 7, 2022

(30) Foreign Application Priority Data
Mar. 9, 2020 (JP) 2020-040086

(51) Int. Cl. B24B 37/04

(52) U.S. Cl. CPC B24B 37/042

(57) ABSTRACT

The present invention relates to a polishing method and a polishing apparatus for polishing a substrate, such as a wafer. The present invention further relates to a computer-readable storage medium storing a program for causing the polishing apparatus to perform the polishing method. The polishing method includes: rotating a polishing table (3); and polishing a substrate (W) by pressing the substrate (W) against a polishing surface (2a). Polishing the substrate (W) includes a film-thickness profile adjustment process and a polishing-end-point detection process. The film-thickness profile adjustment process includes adjusting pressing forces on the substrate (W) against the polishing surface (2a) based on a plurality of film thicknesses, and determining a point in time at which a film-thickness index value has reached a film-thickness threshold value. The film-thickness index value is determined from at least one of the plurality of film thicknesses. The polishing-end-point detection process includes measuring a torque for rotating the polishing table (3) and determining a polishing end point based on the torque.

### TECHNICAL FIELD

The present invention relates to a polishing method and a polishing apparatus for polishing a substrate, such as a wafer. The present invention further relates to a computer-readable storage medium storing a program for causing a polishing apparatus to perform a polishing method.

### BACKGROUND ART

In recent years, with higher integration and higher density of semiconductor devices, interconnects of circuits have become finer and finer, the number of layers of multi-layer interconnects has also increased. Multilayer interconnections in smaller circuits result in greater steps which reflect surface irregularities on lower interconnection layers. An increase in the number of interconnection layers makes film coating performance (step coverage) poor over stepped configurations of thin films. Therefore, better multilayer interconnections need to have the improved step coverage, and proper surface planarization should be performed.

Therefore, in manufacturing process of semiconductor devices, planarization of surfaces of the semiconductor devices is becoming more and more important. The most important technique for planarizing the surface is chemical mechanical polishing (CMP). In this chemical mechanical polishing (hereinafter referred to as CMP), a polishing liquid containing abrasive grains, such as silica (SiO₂), is supplied onto a polishing surface of a polishing pad, and a substrate, such as a wafer, is brought into sliding contact with the polishing surface, so that the substrate is polished.

A polishing apparatus for performing CMP includes a polishing table for supporting a polishing pad having a polishing surface, and a polishing head for holding a substrate. In such a polishing apparatus, the polishing table and the polishing head are moved relative to each other, and the polishing liquid, such as a slurry, is supplied onto the polishing surface of the polishing pad while the substrate is pressed by the polishing head against the polishing surface of the polishing pad. The surface of the substrate is placed in sliding contact with the polishing surface in the presence of the polishing liquid, so that the surface of the substrate is planarized to a mirror finish by a chemical action of the polishing liquid and a mechanical action of abrasive grains contained in the polishing liquid.

A substrate, such as wafer, has a multilayered structure made of different materials including semiconductor, conductive material, and dielectric material. A frictional force acting between the substrate and the polishing pad changes depending on a material of the surface, to be polished, of the substrate. Therefore, conventionally, there is a method including the steps of detecting a change in the frictional force caused by changing of a material of the surface, to be polished, of the substrate to a different material, and determining a polishing end point based on a point in time at which the frictional force changes. The frictional force acts at a position away from the center of rotation (central axis) of the polishing table. Therefore, the change in the frictional force can be detected as a change in torque for rotating the polishing table. In a case where an electric motor is used to rotate the polishing table is, the torque can be measured as a current flowing to the electric motor.

### CITATION LIST

### Patent Literature

Patent document 1: Japanese laid-open patent publication No. 2013-219248

Patent document 2: Japanese laid-open patent publication No. 2005-11977

Patent document 3: Japanese laid-open patent publication No. 2014-3063

### SUMMARY OF INVENTION

### Technical Problem

However, when the substrate has non-uniform thickness of a film constituting the surface to be polished, the change in the torque does not remarkably reflect the change in the frictional force acting between the substrate and the polishing pad. As a result, the polishing end point may not be accurately determined.

Therefore, the present invention provides a polishing method and a polishing apparatus which can accurately determine a polishing end point of a substrate. The present invention further provides a computer-readable storage medium storing a program for causing the polishing apparatus to perform such a polishing method.

### Solution to Problem

In an embodiment, there is provided a polishing method comprising: rotating a polishing table that supports a polishing pad; and polishing a substrate by pressing the substrate against a polishing surface of the polishing pad by a polishing head, the substrate having a multilayered structure including a dielectric film and a stopper layer formed under the dielectric film, wherein polishing the substrate includes a film-thickness profile adjustment process and a polishing-end-point detection process performed after the film-thickness profile adjustment process, the film-thickness profile adjustment process includes measuring a plurality of film thicknesses at a plurality of measurement points on the substrate, adjusting pressing forces on the substrate against the polishing surface based on the plurality of film thicknesses, and determining a point in time at which a film-thickness index value has reached a film-thickness threshold value, the film-thickness index value being determined from at least one of the plurality of film thicknesses, and the polishing-end-point detection process includes measuring a torque for rotating the polishing table and determining a polishing end point of the substrate based on the torque.

In an embodiment, adjusting the pressing forces includes adjusting the pressing forces on the substrate against the polishing surface based on the plurality of film thicknesses such that a surface, to be polished, of the substrate becomes flat.

In an embodiment, measuring the plurality of film thicknesses includes irradiating the substrate with light, generating a plurality of spectra of reflected light from the plurality of measurement points on the substrate, and determining the plurality of film thicknesses based on the plurality of spectra.

In an embodiment, polishing the substrate further includes an initial polishing process performed before the film-thickness profile adjustment process, the initial polishing process including measuring a torque for rotating the polishing table and determining an initial polishing end point based on the torque.

In an embodiment, there is provided a computer-readable storage medium storing a program for causing a computer to perform: instructing a table motor to rotate a polishing table that supports a polishing pad; instructing a plurality of pressure regulators to adjust pressing forces on a substrate against a polishing surface of the polishing pad based on a plurality of film thicknesses at a plurality of measurement points on the substrate when a polishing head is pressing the substrate against the polishing surface to polish the substrate, the polishing head having a plurality of pressure chambers coupled to the plurality of pressure regulators: determining a point in time at which a film-thickness index value has reached a film-thickness threshold value, the film-thickness index value being determined from at least one of the plurality of film thicknesses; and determining a polishing end point of the substrate based on a torque for rotating the polishing table after determination of the point in time at which the film-thickness index value has reached the film-thickness threshold value.

In an embodiment, instructing the plurality of pressure regulators to adjust the pressing forces on the substrate against the polishing surface comprises instructing the plurality of pressure regulators to adjust the pressing forces on the substrate against the polishing surface based on the plurality of film thicknesses at the plurality of measurement points such that a surface, to be polished, of the substrate becomes flat.

In an embodiment, the program is configured to cause the computer to further perform determining an initial polishing end point based on a torque for rotating the polishing table when the substrate is being polished and before the plurality of pressure regulators adjust the pressing forces on the substrate against the polishing surface.

In an embodiment, there is provided a polishing apparatus for polishing a substrate having a multilayered structure including a dielectric film and a stopper layer formed under the dielectric film, comprising: a polishing table configured to support a polishing pad; a table motor configured to rotate the polishing table; a polishing head having a plurality of pressure chambers for pressing the substrate against a polishing surface of the polishing pad; a film-thickness measuring device configured to measure a plurality of film thicknesses at a plurality of measurement points on the substrate; a plurality of pressure regulators coupled to the plurality of pressure chambers; a torque measuring device configured to measure a torque for rotating the polishing table; and an operation controller configured to control operations of the polishing apparatus, wherein the operation controller is configured to: perform a film-thickness profile adjustment process of instructing the plurality of pressure regulators to adjust pressing forces on the substrate against the polishing surface based on the plurality of film thicknesses during polishing of the substrate, and determining a point in time at which a film-thickness index value has reached a film-thickness threshold value, the film-thickness index value being determined from at least one of the plurality of film thicknesses; and determine a polishing end point of the substrate based on the torque during polishing of the substrate and after the film-thickness profile adjustment process.

In an embodiment, the operation controller is configured to instruct the plurality of pressure regulators to adjust the pressing forces on the substrate against the polishing surface based on the plurality of film thicknesses such that a surface, to be polished, of the substrate becomes flat.

In an embodiment, the film-thickness measuring device is an optical film-thickness measuring device configured to measure a film thickness of the substrate based on a spectrum of reflected light from the substrate.

In an embodiment, the operation controller is configured to determine an initial polishing end point based on the torque for rotating the polishing table during polishing of the substrate and before the film-thickness profile adjustment process.

### Advantageous Effects of Invention

According to the present invention, the polishing apparatus performs the film-thickness profile adjustment process of polishing the substrate while adjusting the pressing forces on the substrate against the polishing pad based on the film thicknesses at the measurement points on the substrate, and then performs the polishing-end-point detecting process of determining the polishing end point of the substrate based on the torque for rotating the polishing table. The polishing apparatus can measure the torque with the adjusted film-thickness profile of the substrate, and can therefore accurately determine the polishing end point of the substrate.

### BRIEF DESCRIPTION OF DRAWINGS

FIG. 1 is a schematic diagram showing an embodiment of a polishing apparatus.

FIG. 2 is a diagram showing an example of a spectrum generated by a processing system.

FIG. 3 is a schematic diagram showing an example of a plurality of measurement points on a surface (polishing-target surface) of a substrate.

FIG. 4 is a sectional diagram of a polishing head shown in FIG. 1.

FIG. 5A is a diagram showing a substrate before being polished.

FIG. 5B is a diagram showing the substrate when a dielectric film is polished until a film-thickness index value reaches a film-thickness threshold value.

FIG. 5C is a diagram showing the substrate which has been polished to a polishing end point.

FIG. 6 is a flowchart showing an embodiment of a polishing method for a substrate and a method of determining a polishing end point of the substrate.

FIG. 7 is a diagram showing measured value of a drive current of a table motor in each polishing process.

FIG. 8 is a diagram showing a substrate which has been polished to an initial polishing end point.

### DESCRIPTION OF EMBODIMENTS

Hereinafter, embodiments of the present invention will be described in detail with reference to the drawings.

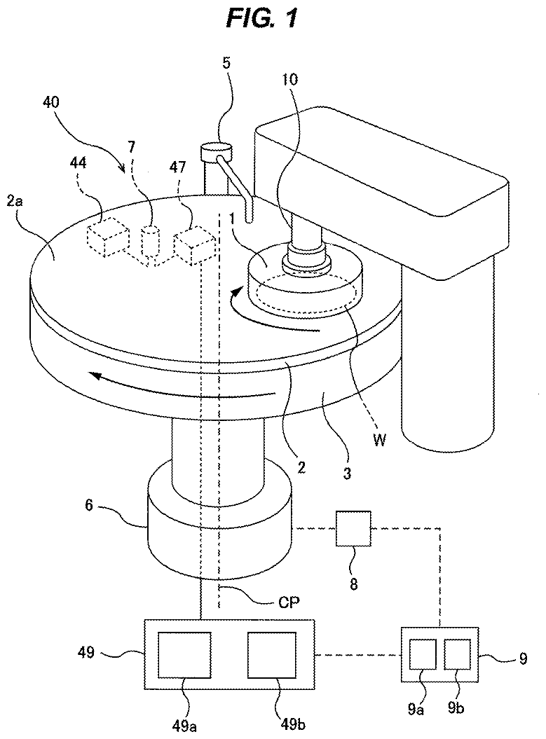

FIG. 1 is a schematic diagram showing an embodiment of a polishing apparatus. As shown in FIG. 1, the polishing apparatus includes a polishing table 3 that supports a polishing pad 2, a polishing head 1 configured to press a substrate W (e.g., a wafer) having a film against the polishing pad 2, a table motor 6 configured to rotate the polishing table 3, a polishing-liquid supply nozzle 5 configured to supply a polishing liquid, such as a slurry, onto the polishing pad 2, a film-thickness measuring device 40 (or an optical film-thickness measuring device 40) configured to measure a film thickness of the substrate W, a torque measuring device 8 configured to measure a torque for rotating the polishing table 3, and an operation controller 9 configured to control operations of the polishing apparatus. An upper surface of the polishing pad 2 constitutes a polishing surface 2a for polishing the substrate W.

In the present embodiment, an object to be polished is a substrate having a multilayered structure. The substrate W has a multilayered structure including a dielectric film and a stopper layer formed under the dielectric film. In the present embodiment, the dielectric film is formed of silicon dioxide (SiO₂) and the stopper layer is formed of silicon nitride (Si₃N₄), but the configurations of the dielectric film and the stopper layer are not limited to this embodiment. In one embodiment, the stopper layer may be formed of a material that is not removed by an etching liquid for removing the dielectric film and is removed by an etching liquid that does not damage the dielectric film.

The polishing head 1 is coupled to a head shaft 10, and the head shaft 10 is coupled to a polishing-head motor (not shown) via a connecting means, such as a belt. The polishing-head motor is configured to rotate the polishing head 1 together with the head shaft 10 in a direction indicated by arrow. The polishing table 3 is coupled to the table motor 6. The table motor 6 is configured to rotate the polishing table 3 and the polishing pad 2 in a direction indicated by arrow. The rotating directions of the polishing head 1 and the polishing table 3 are not limited to this embodiment. In one embodiment, the polishing head 1 and the polishing table 3 may be configured to rotate in directions opposite to the directions indicated by the arrows in FIG. 1.

The substrate W is polished as follows. While the polishing table 3 and the polishing head 1 are rotated in the directions indicated by the arrows in FIG. 1, the polishing liquid is supplied from the polishing-liquid supply nozzle 5 to the polishing surface 2a of the polishing pad 2 on the polishing table 3. While the substrate W is rotated by the polishing head 1, the substrate W is pressed against the polishing surface 2a of the polishing pad 2 by the polishing head 1 in the presence of the polishing liquid on the polishing pad 2. The surface of the substrate W is polished by the chemical action of the polishing liquid and the mechanical action of the abrasive grains contained in the polishing liquid or the polishing pad 2.

The operation controller 9 is composed of at least one computer. The operation controller 9 includes a memory 9a in which programs are stored, and an arithmetic device 9b configured to perform arithmetic operations according to instructions contained in the programs. The arithmetic device 9b includes a CPU (central processing unit) or a GPU (graphic processing unit) configured to perform an arithmetic operation according to instructions contained in the programs stored in the memory 9a. The memory 9a includes a main memory (for example, a random access memory) to which the arithmetic device 9b is accessible, and an auxiliary memory (for example, a hard disk drive or a solid state drive) for storing data and the programs.

The torque measuring device 8 is coupled to the table motor 6. During polishing of the substrate W, the polishing table 3 is driven by the table motor 6 so as to rotate at a constant speed. Therefore, when the torque required to rotate the polishing table 3 at a constant speed changes, a drive current for the table motor 6 changes.

The torque for rotating the polishing table 3 is a moment of force for rotating the polishing table 3 around its axis CP. The torque for rotating the polishing table 3 corresponds to the drive current of the table motor 6. Therefore, in the present embodiment, the torque measuring device 8 is a current measuring device configured to measure the drive current of the table motor 6. In one embodiment, the torque measuring device 8 may be composed of at least a part of a motor driver for driving the table motor 6. In this case, the motor driver determines the current value required for rotating the polishing table 3 at a constant speed, and outputs the determined current value. The determined current value corresponds to the torque for rotating the polishing table 3. In one embodiment, the torque measuring device 8 may be a torque measuring device that directly measures the torque for rotating the polishing table 3 around its axis CP.

The torque measuring device 8 is coupled to the operation controller 9. The operation controller 9 controls the polishing operation for the substrate W based on the torque measured by the torque measuring device 8. For example, the operation controller 9 determines a polishing end point of the substrate W based on the torque measured by the torque measuring device 8.

The film-thickness measuring device 40 of the present embodiment is an optical film-thickness measuring device configured to direct light to the surface of the substrate W and determine a film thickness of the substrate W based on intensity measurement data of reflected light from the substrate W. The optical film-thickness measuring device 40 includes a light source 44 configured to emit light, a spectrometer 47, an optical sensor head 7 coupled to the light source 44 and the spectrometer 47, and a processing system 49 coupled to the spectrometer 47. The optical sensor head 7, the light source 44, and the spectrometer 47 are attached to the polishing table 3 and rotate together with the polishing table 3 and the polishing pad 2. The position of the optical sensor head 7 is such that the optical sensor head 7 sweeps across the surface of the substrate W on the polishing pad 2 each time the polishing table 3 and the polishing pad 2 make one rotation.

The processing system 49 includes a memory 49a storing therein programs for generating a spectrum and detecting a film thickness of the substrate W which will be described later, and an arithmetic device 49b configured to perform arithmetic operations according to instructions contained in the programs. The processing system 49 is composed of at least one computer. The memory 49a includes a main memory, such as a RAM, and an auxiliary memory, such as a hard disk drive (HDD) or a solid state drive (SSD). Examples of the arithmetic unit 49b include a CPU (central processing unit) and a GPU (graphic processing unit). However, the specific configuration of the processing system 49 is not limited to these examples.

The light emitted from the light source 44 is transmitted to the optical sensor head 7 and directed from the optical sensor head 7 to the surface of the substrate W. The light is reflected off the surface of the substrate W, and the reflected light from the surface of the substrate W is received by the optical sensor head 7 and transmitted to the spectrometer 47. The spectrometer 47 decomposes the reflected light according to wavelengths and measures intensity of the reflected light at each of the wavelengths. The intensity measurement data of the reflected light is sent to the processing system 49.

The processing system 49 is configured to generate a spectrum of the reflected light from the intensity measurement data of the reflected light. The spectrum of the reflected light is represented as a line graph (i.e., a spectral waveform) showing a relationship between the wavelength and the intensity of the reflected light. The intensity of the reflected light can also be expressed as a relative value, such as reflectance or relative reflectance.

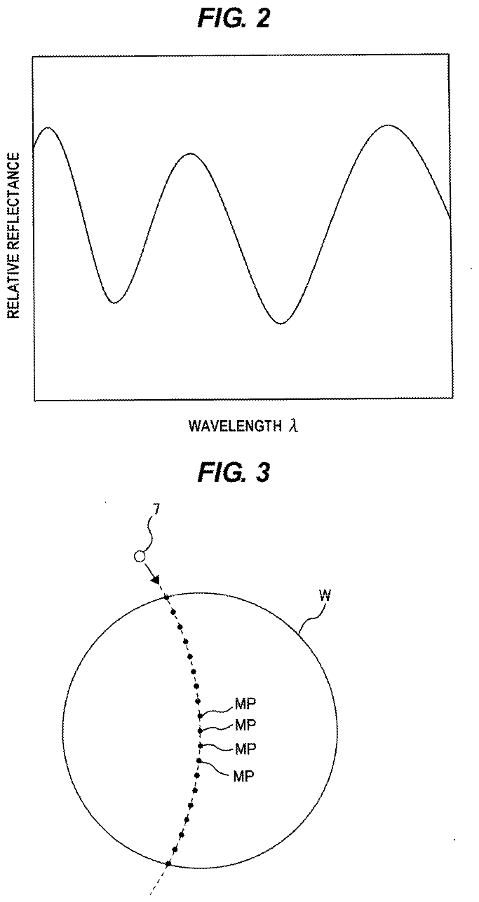

FIG. 2 is a diagram showing an example of a spectrum generated by the processing system 49. The spectrum is represented as a line graph (i.e., a spectral waveform) showing a relationship between the wavelength and the intensity of light. In FIG. 2, a horizontal axis represents the wavelength of the light reflected from the substrate, and a vertical axis represents the relative reflectance derived from the intensity of the reflected light. The relative reflectance is an index value indicating the intensity of the reflected light, and is a ratio of the intensity of the light to a predetermined reference intensity. By dividing the intensity of the light (measured intensity) by a predetermined reference intensity at each of wavelengths, unnecessary noise, such as variation in the intensity inherent in an optical system or a light source of the device, can be removed from the measured intensity.

The reference intensity is an intensity of light measured in advance for each of wavelengths, and the relative reflectance is calculated for each of the wavelengths. Specifically, the relative reflectance is obtained by dividing a light intensity (measured intensity) at each wavelength by a corresponding reference intensity. The reference intensity is obtained, for example, by directly measuring an intensity of the light emitted from the optical sensor head 7, or by irradiating a mirror with the light from the optical sensor head 7 and measuring the intensity of the reflected light from the mirror. Alternatively, the reference intensity may be an intensity of reflected light from a silicon substrate (or a bare substrate) having no film thereon measured by the spectrometer 47 when the silicon substrate (or the bare substrate) is water-polished in the presence of water on the polishing pad 2 or when the silicon substrate (or the bare substrate) is placed on the polishing pad 2.

In actual polishing, a dark level (or a background intensity obtained under a condition that light is blocked) is subtracted from a measured intensity to determine a corrected measured intensity, and the dark level is subtracted from the reference intensity to determine a corrected reference intensity. Then, the relative reflectance is determined by dividing the corrected measured intensity by the corrected reference intensity. Specifically, the relative reflectance R(λ) can be determined by using the following formula (1).

$$R ( λ ) = \frac{E ( λ ) - D ( λ )}{B ( λ ) - D ( λ )} \qquad ( 1 )$$

where, λ is the wavelength of the light reflected from the substrate, E(λ) is the intensity at the wavelength λ, B(λ) is the reference intensity at the wavelength λ, and D(λ) is the background intensity (dark level) at the wavelength λ measured under the condition that light is blocked.

Each time the polishing table 3 makes one rotation, the optical sensor head 7 directs the light to the surface (i.e., the surface to be polished) of the substrate W and receives the reflected light from the substrate W. The reflected light is transmitted to the spectrometer 47. The spectrometer 47 decomposes the reflected light according to the wavelengths and measures the intensity of the reflected light at each of the wavelengths. Intensity measurement data of the reflected light is sent to the processing system 49, and the processing system 49 generates a spectrum as shown in FIG. 2 from the intensity measurement data of the reflected light. Further, the processing system 49 determines a film thickness of the substrate W from the spectrum of the reflected light. The spectrum of the reflected light changes according to the film thickness of the substrate W. Therefore, the processing system 49 can determine the film thickness of the substrate W from the spectrum of the reflected light. A known technique can be used as a specific method for determining the film thickness of the substrate W from the spectrum of the reflected light. In the example shown in FIG. 2, the spectrum of the reflected light is a spectral waveform showing the relationship between the relative reflectance and the wavelength of the reflected light, while the spectrum of the reflected light may be a spectral waveform showing a relationship between the intensity itself of the reflected light and the wavelength of the reflected light.

The processing system 49 is composed of at least one computer. The at least one computer may be one server or a plurality of servers. The processing system 49 may be an edge server coupled to the spectrometer 47 by a communication line, or may be a cloud server coupled to the spectrometer 47 by a communication network, such as the Internet or a local area network. Alternatively, the processing system 49 may be a fog computing device (gateway, fog server, router, etc.) installed in a network coupled to the spectrometer 47.

The processing system 49 may be a plurality of servers coupled by a communication network, such as the Internet or a local area network. For example, the processing system 49 may be a combination of an edge server and a cloud server.

The processing system 49 is coupled to the operation controller 9. The operation controller 9 is configured to control the polishing operation for the substrate W based on the film thickness of the substrate W determined by the processing system 49. For example, the operation controller 9 instructs a pressure regulator (which will be described later) to adjust a pressing force on the substrate W against the polishing surface 2a based on the film thickness of the substrate W.

The optical film-thickness measuring device 40 of the present embodiment is configured to measure a plurality of film thicknesses at a plurality of measurement points on the substrate W. In the present embodiment, while the optical sensor head 7 sweeps across the substrate W once, the optical sensor head 7 emits the light to a plurality of measurement points on the substrate W and receives the reflected light from the plurality of measurement points. In the present embodiment, only one optical sensor head 7 is provided in the polishing table 3, but a plurality of optical sensor heads 7 may be provided in the polishing table 3.

FIG. 3 is a schematic diagram showing an example of a plurality of measurement points on the surface (i.e., the surface to be polished) of the substrate W. As shown in FIG. 3, the optical sensor head 7 directs the light to a plurality of measurement points MP each time the optical sensor head 7 moves across the substrate W, and receives the reflected light from the plurality of measurement points MP. Therefore, each time the optical sensor head 7 moves across the substrate W (i.e., each time the polishing table 3 makes one rotation), the processing system 49 generates a plurality of spectra of the reflected light from the plurality of measurement points MP and determines film thicknesses at the respective measurement points MP based on the plurality of spectra. A position of each measurement point MP is determined based on a light irradiation timing, a rotation speed of the polishing table 3, a position of the polishing head 1, a rotation speed of the polishing head 1, etc.

As will be described later, a substrate pressing surface of the polishing head 1 is divided into a plurality of zones for pressing a plurality of regions of the substrate W against the polishing surface 2a of the polishing pad 2. The polishing head 1 is configured to independently regulate loads on the plurality of regions of the substrate W. The polishing head 1 can regulate the pressing forces on the substrate W against the polishing surface 2a based on the film thicknesses of the substrate W corresponding to the plurality of regions of the substrate W. In the present embodiment, the film-thickness measuring device 40 is an optical film-thickness measuring device, while the film-thickness measuring device 40 is not limited to the optical film-thickness measuring device as long as it can measure a plurality of film thicknesses of the dielectric film at the plurality of measurement points on the substrate W.

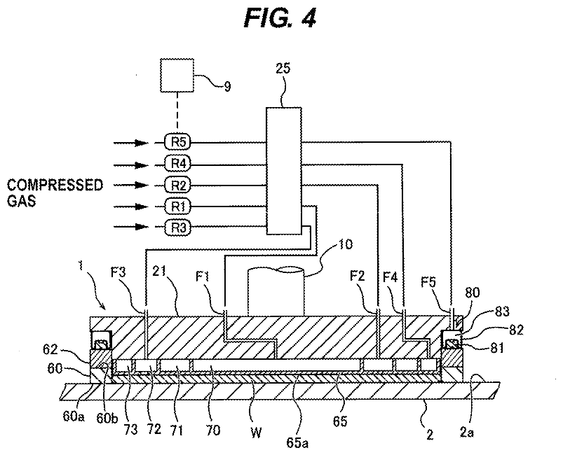

Next, the details of the polishing head 1 will be described. FIG. 4 is a cross-sectional view of the polishing head 1 shown in FIG. 1. As shown in FIG. 4, the polishing head 1 has an elastic membrane 65 for pressing the substrate W against the polishing surface 2a of the polishing pad 2, a head body 21 that holds the elastic membrane 65, an annular drive ring 62 arranged below the head body 21, and an annular retainer ring 60 fixed to a lower surface of the drive ring 62. The elastic membrane 65 is attached to a lower part of the head body 21. The head body 21 is fixed to an end of the head shaft 10. The head body 21, the elastic membrane 65, the drive ring 62, and the retainer ring 60 are configured to rotate together by the rotation of the head shaft 10. The retainer ring 60 and the drive ring 62 are configured to be movable up and down relative to the head body 21. The head body 21 is made of a resin, such as engineering plastic (for example, PEEK).

The elastic membrane 65 has a lower surface that constitutes a substrate pressing surface 65a for pressing the substrate W against the polishing surface 2a of the polishing pad 2. The retainer ring 60 is arranged so as to surround the substrate pressing surface 65a, and the substrate W is surrounded by the retainer ring 60. Four pressure chambers 70, 71, 72, 73 are provided between the elastic membrane 65 and the head body 21. The pressure chambers 70, 71, 72, 73 are formed by the elastic membrane 65 and the head body 21. The central pressure chamber 70 has a circular shape, and the other pressure chambers 71, 72, 73 have annular shapes. These pressure chambers 70, 71, 72, 73 are concentrically arranged. In the present embodiment, the elastic membrane 65 forms the four pressure chambers 70 to 73, but the number of above-mentioned pressure chambers is an example and may be changed as appropriate.

Gas delivery lines F1, F2, F3, and F4 are coupled to the pressure chambers 70, 71, 72, and 73, respectively. Ends of the gas delivery lines F1, F2, F3, F4 are coupled to a compressed-gas supply source (not shown) as a utility provided in a factory where the polishing apparatus is installed. Compressed gas, such as compressed air, is supplied to the pressure chambers 70, 71, 72, and 73 through the gas delivery lines F1, F2, F3, and F4, respectively. When the compressed gas is supplied to the pressure chambers 70 to 73, the elastic membrane 65 is inflated, and the compressed gas in the pressure chambers 70 to 73 presses the substrate W against the polishing surface 2a of the polishing pad 2 via the elastic membrane 65. The pressure chambers 70 to 73 function as actuators for pressing the substrate W against the polishing surface 2a of the polishing pad 2.

The gas delivery line F3 communicating with the pressure chamber 72 is coupled to a vacuum line (not shown), so that a vacuum can be developed in the pressure chamber 72. An opening is formed in a portion of the elastic membrane 65 constituting the pressure chamber 72, and the substrate W is attracted and held on the polishing head 1 by forming a vacuum in the pressure chamber 72. Further, by supplying the compressed gas to the pressure chamber 72, the substrate W is released from the polishing head 1. The elastic membrane 65 is formed of a rubber material having excellent strength and durability, such as ethylene propylene rubber (EPDM), polyurethane rubber, or silicone rubber.

The retainer ring 60 is an annular member arranged around the elastic membrane 65 and to be brought into contact with the polishing surface 2a of the polishing pad 2. The retainer ring 60 is arranged so as to surround a peripheral edge of the substrate W, and prevents the substrate W from coming off from the polishing head 1 during polishing of the substrate W.

An upper portion of the drive ring 62 is coupled to an annular retainer-ring pressing device 80. The retainer-ring pressing device 80 is configured to apply a downward load to an entire upper surface 60b of the retainer ring 60 via the drive ring 62, whereby a lower surface 60a of the retainer ring 60 is pressed against the polishing surface 2a of the polishing pad 2.

The retainer-ring pressing device 80 includes an annular piston 81 fixed to the upper part of the drive ring 62 and an annular rolling diaphragm 82 coupled to an upper surface of the piston 81. A retainer-ring pressure chamber 83 is formed inside the rolling diaphragm 82. The retainer-ring pressure chamber 83 is coupled to the compressed-gas supply source via a gas delivery line F5. The compressed gas is supplied into the retainer-ring pressure chamber 83 through the gas delivery line F5.

When the compressed gas is supplied to the retainer-ring pressure chamber 83 from the compressed-gas supply source, the rolling diaphragm 82 pushes down the piston 81, the piston 81 pushes down the drive ring 62, and the drive ring 62 in turn pushes down the entire retainer ring 60. In this way, the retainer-ring pressing device 80 presses the lower surface 60a of the retainer ring 60 against the polishing surface 2a of the polishing pad 2. The drive ring 62 is removably coupled to the retainer-ring pressing device 80.

The gas delivery lines F1, F2, F3, F4, F5 extend via a rotary joint 25 attached to the head shaft 10. The polishing apparatus further includes pressure regulators R1, R2, R3, R4, R5, which are provided in the gas delivery lines F1, F2, F3, F4, F5, respectively. The compressed gas from the compressed-gas supply source is independently supplied into the pressure chambers 70 to 73 and the retainer-ring pressure chamber 83 through the pressure regulators R1 to R5. The pressure regulators R1 to R5 are configured to regulate the pressures of the compressed gas in the pressure chambers 70 to 73 and the retainer-ring pressure chamber 83. The pressure regulators R1 to R5 are coupled to the operation controller 9.

The pressure regulators R1 to R5 can change the pressures in the pressure chambers 70 to 73 and the retainer-ring pressure chamber 83 independently of each other. Therefore, the pressure regulators R1 to R5 can independently regulate the pressing forces on corresponding four regions of the substrate W, i.e., a central region, an inner intermediate region, an outer intermediate region, and an edge region of the substrate W against the polishing surface 2a of the polishing pad 2 and the pressing force on the retainer ring 60 against the polishing pad 2. The gas delivery lines F1, F2, F3, F4, and F5 are coupled to vent valves (not shown), so that the pressure chambers 70 to 73 and the retainer-ring pressure chamber 83 can be ventilated to the atmosphere. In the present embodiment, the elastic membrane 65 forms four pressure chambers 70 to 73, but in one embodiment, the elastic membrane 65 may form less than four pressure chambers or more than four pressure chambers.

Film thickness data of the plurality of film thicknesses at the plurality of measurement points of the substrate W measured by the film-thickness measuring device 40 shown in FIG. 1 is sent to the operation controller 9. The operation controller 9 instructs the pressure regulators R1 to R4 to independently adjust the pressing forces that press the corresponding four regions of the substrate W against the polishing surface 2a based on the plurality of film thicknesses measured by the film-thickness measuring device 40. As an example, the operation controller 9 compares a film thickness of the central region of the substrate W with a film thickness of the other region, and when the film thickness of the central region is larger than the film thickness of the other region, the operation controller 9 instructs the pressure regulator R1 to increase the pressure in the pressure chamber 70.

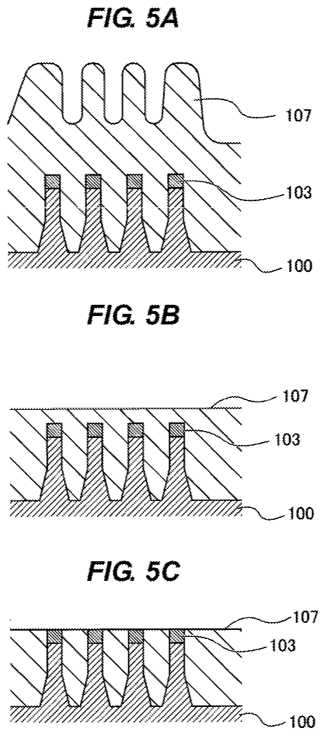

Hereinafter, details of a method of polishing a substrate and a method of determining a polishing end point of the substrate will be described with reference to a substrate shown in FIGS. 5A to 5C as an example. The substrate shown in FIGS. 5A to 5C has a silicon (Si) layer 100 having a stepped surface, a stopper layer 103 made of silicon nitride (Si₃N₄) formed on raised portions of the silicon layer 100, and a dielectric film 107 made of silicon dioxide (SiO₂) formed on the stopper layer 103. The stopper layer 103 has a property that the stopper layer 103 is not removed by an etching liquid for removing the dielectric film 107. In this embodiment, a method of polishing the dielectric film 107 until the surface of the stopper layer 103 is exposed will be described. FIG. 5A shows the substrate W before being polished, and FIG. 5B shows the substrate W when the dielectric film 107 is polished until a film-thickness index value reaches a film-thickness threshold value as described later. FIG. 5C shows the substrate W that has been polished to a polishing end point. Examples of a multilayered structure shown in FIGS. 5B and 5C include shallow trench isolation (STI). Therefore, the polishing method of the present embodiment can be applied to a process of manufacturing shallow trench isolation (STI).

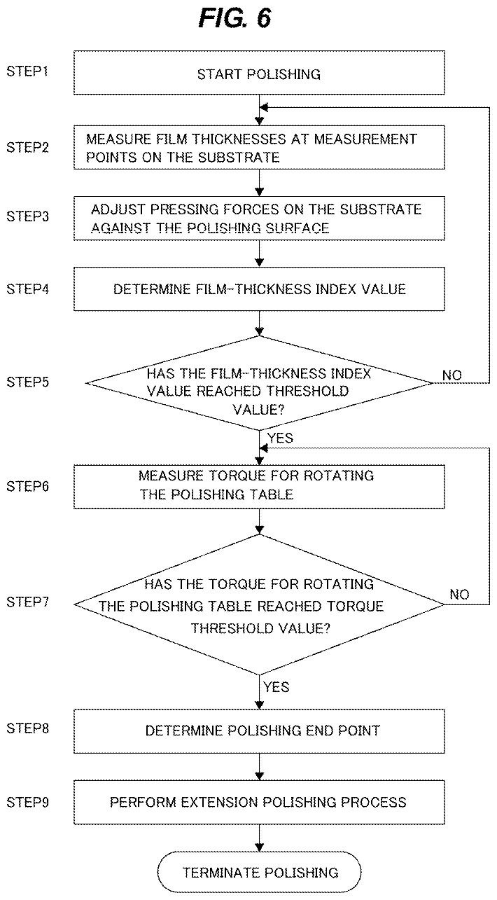

FIG. 6 is a flowchart showing an embodiment of the method of polishing the substrate W and the method of determining the polishing end point of the substrate W.

In step 1, the polishing apparatus starts the polishing operation. Specifically, the table motor 6 rotates the polishing table 3 together with the polishing pad 2 at a constant rotation speed, and the polishing head 1 rotates the substrate W at a constant rotation speed. The polishing head 1 presses the substrate W against the polishing surface 2a of the polishing pad 2 to start polishing of substrate W.

In steps 2 to 5, the polishing apparatus performs a film-thickness profile adjustment process. The film-thickness profile adjustment process includes measuring a plurality of film thicknesses at a plurality of measurement points on the substrate W during polishing of the substrate W, adjusting the pressing forces on the substrate W against the polishing surface 2a based on the plurality of film thicknesses, and determining a point in time at which the film-thickness index value has reached the film-thickness threshold value. The film-thickness index value is determined from at least one of the plurality of film thicknesses. The film thicknesses measured in the film-thickness profile adjustment process are the thicknesses of the dielectric film 107.

In step 2, the film-thickness measuring device 40 measures the plurality of film thicknesses at the plurality of measurement points on the substrate W. Specifically, the optical film-thickness measuring device 40 irradiates the substrate W with the light a plurality of times when the optical sensor head 7 sweeps across the substrate W, and measures the intensity of the plurality of reflected lights at each of wavelengths. The optical film-thickness measuring device 40 generates a plurality of spectra of the reflected lights from intensity measurement data of the plurality of reflected lights. The optical film-thickness measuring device 40 determines a plurality of film thicknesses at the plurality of measurement points based on the plurality of spectra. The operation controller 9 instructs the optical film-thickness measuring device 40 to perform the step 2.

In step 3, the pressing forces on the substrate W against the polishing surface 2a are adjusted based on the plurality of film thicknesses measured in the step 2. Specifically, the operation controller 9 obtains the film thickness data measured in the step 2 from the optical film-thickness measuring device 40, determines the pressures in the pressure chambers 70 to 73 of the polishing head 1 based on the plurality of film thicknesses, and instructs at least one of the pressure regulators R1 to R4 to adjust the pressing force(s) on the substrate W against the polishing surface 2a.

The operation controller 9 may generate a film-thickness profile showing a relationship between a plurality of positions on the substrate W and a plurality of film thicknesses at the plurality of positions. The operation controller 9 may determine the pressures in the pressure chambers 70 to 73 of the polishing head 1 based on the film-thickness profile. The pressure regulator to be instructed may be one or two or more pressure regulators. When a plurality of measurement points exist in any one of the four regions of the substrate W described above, the operation controller 9 may determine a film thickness of that region by calculating an average of film thicknesses at the plurality of measurement points in that region. In one embodiment, the film thickness in each region may be a film thickness at one measurement point arbitrarily selected from a plurality of measurement points in each region. In one embodiment, the film thickness in each region may be a maximum or a minimum of a plurality of film thicknesses in reach region.

An example of the step 3 will be described below. The operation controller 9 receives the film thickness data measured in the step 2 from the optical film-thickness measuring device 40, and generate a film-thickness profile representing the relationship between the plurality of positions on the substrate W and the plurality of film thicknesses at the plurality of positions on the substrate W. The operation controller 9 determines the film thickness of the corresponding four regions of the substrate W (i.e., the central region, the inner intermediate region, the outer intermediate region, and the edge region) based on the film-thickness profile. When there are a plurality of measurement points in each region, the operation controller 9 determines the film thickness of each region by calculating an average of the film thicknesses at the plurality of measurement points in each region.

As an example, the operation controller 9 compares a film thickness of the central region of the substrate W with a film thickness of the other region. When the film thickness in the central region is larger than the film thickness in the other region, the operation controller 9 instructs the pressure regulator R1 to increase the pressure in the pressure chamber 70. When the film thickness in the central region is smaller than the film thickness in the other region, the operation controller 9 instructs the pressure regulator R1 to lower the pressure in the pressure chamber 70.

In this way, the polishing apparatus can adjust the film-thickness profile of the substrate W by changing the internal pressures of the pressure chambers 70 to 73 independently of each other based on the plurality of film thicknesses of the substrate W. In the present embodiment, the operation controller 9 instructs the pressure regulators R1 to R4 to adjust the pressing forces on the substrate W against the polishing surface 2a based on the plurality of film thicknesses of the substrate W such that the surface, to be polished, of the substrate W becomes flat (i.e., the thickness of the film constituting the surface, to be polished, of the substrate W is made uniform). As a result, the polishing apparatus can accurately perform a polishing-end-point detection process described later.

In step 4, the operation controller 9 determines the film-thickness index value from at least one of the plurality of film thicknesses at the plurality of measurement points on the substrate W measured in the step 2. In the present embodiment, the film-thickness index value is determined by calculating an average of the plurality of film thicknesses. In one embodiment, the film-thickness index value may be a film thickness at one measurement point arbitrarily selected from the plurality of measurement points. In another embodiment, the film-thickness index value may be a maximum or a minimum of the plurality of film thicknesses.

In step 5, the operation controller 9 determines a point in time at which the film-thickness index value has reached the film-thickness threshold value. Specifically, the operation controller 9 compares the film-thickness index value with the film-thickness threshold value, and if the film-thickness index value does not reach the film-thickness threshold value, the process flow goes back to the step 2 and the operation controller 9 performs the steps 2 to 5 again. When the film-thickness index value has reached the film-thickness threshold value, the polishing apparatus terminates the film-thickness profile adjustment process and performs the polishing-end-point detection process.

The film thickness threshold is determined in advance based on experiments or past polishing results. The film-thickness threshold value is determined based on a point in time at which the thickness of the dielectric film 107 is thin enough for the polishing-end-point detection process, which will be described later, to be able to accurately detect the polishing end point. FIG. 5B shows the substrate W that has been polished until the film-thickness index value has reached the film-thickness threshold value.

In steps 6 to 8, the polishing apparatus performs the polishing-end-point detection process. The polishing-end-point detection process includes measuring the torque for rotating the polishing table 3 during polishing of the substrate W, and determining the polishing end point of the substrate W based on the torque.

In step 6, the torque measuring device 8 measures the torque for rotating the polishing table 3. Specifically, the operation controller 9 instructs the torque measuring device 8 to measure the torque for rotating the polishing table 3. In the present embodiment, the torque measuring device 8 is a current measuring device, and the torque measuring device 8 measures the drive current of the table motor 6 corresponding to the torque for rotating the polishing table 3.

In steps 7 and 8, the operation controller 9 determines the polishing end point of the substrate W based on the torque measured in the step 6. Specifically, the operation controller 9 obtains the measured value of the torque from the torque measuring device 8 and compares the measured value of the torque with a preset torque threshold value (step 7). The measured value of this torque represents a torque required for rotating the polishing table 3 at a constant speed. When the measured value of the torque does not reach the torque threshold value, the process flow goes back to the step 6 and the operation controller 9 performs the steps 6 and 7 again. When the measured value of the torque has reached the torque threshold value, the operation controller 9 determines the polishing end point at which the measured value of the torque has reached the torque threshold value (step 8). Thereafter, the operation controller 9 terminates the polishing-end-point detection process.

In one embodiment, the operation controller 9 may calculate a rate of change in the torque for rotating the polishing table 3 based on the torque measured in the step 6, and may compare the calculated rate of change in the torque with a preset rate-of-change threshold value. The rate of change in the torque represents an amount of change in the torque per unit time. If the rate of change in the torque does not reach the rate-of-change threshold value, the process flow goes back to the step 6 and the operation controller 9 performs the steps 6 and 7 again. When the rate of change in the torque has reached the rate-of-change threshold value, the operation controller 9 may determine a polishing end point at which the rate of change in the torque has reached the rate-of-change threshold value.

FIG. 5C shows the substrate W that has been polished until the polishing end point is reached. The polishing end point is a point in time at which the dielectric film 107 on the stopper layer 103 is removed by the polishing operation and the entire surface of the stopper layer 103 is exposed. The torque for rotating the polishing table 3 (which is proportional to the frictional force acting between the polishing pad 2 and the substrate W) changes as the thickness of the dielectric film 107 on the stopper layer 103 decreases. When the surface of the stopper layer 103 is completely exposed, the above torque no longer changes. Therefore, the operation controller 9 can determine the polishing end point based on the measured value of the torque or the rate of change in the measured value of the torque at a point in time at which the torque no longer changes. The torque threshold value and the rate-of-change threshold value are predetermined based on experiments or past polishing results.

In step 9, the polishing apparatus performs an extension polishing process. In the extension polishing process, the polishing apparatus polishes the substrate W for a predetermined extension time according to the above-described step 1. The dielectric film 107 on the stopper layer 103 can be completely removed by polishing the substrate W even after the polishing end point has elapsed. The extension time is predetermined based on experiments or past polishing results. After the extension time has elapsed, the polishing apparatus terminates the extension polishing process. As a result, the polishing of the substrate W is completed. The extension polishing process may be omitted. When the extension polishing process is omitted, the polishing of the substrate W is terminated when the polishing end point is detected in the step 8.

If a thickness of a film constituting the surface, to be polished, of the substrate W (e.g., the dielectric film 107 in the example shown in FIG. 5A) is non-uniform, the change in torque for rotating the table 3 (i.e., the change in drive current of the table motor 6) may not remarkably reflect the change in the frictional force acting between the substrate W and the polishing pad 2. As a result, the polishing end point may not be accurately determined. According to the present embodiment, since the film-thickness profile adjustment process is performed before the polishing-end-point detection process, the polishing-end-point detection process can be performed under the condition that the film-thickness profile of the substrate W has been controlled to a desired profile. For example, the polishing apparatus can perform the polishing-end-point detection process under the condition that the surface, to be polished, of the substrate W is flat (i.e., under the condition that the substrate W has a good surface uniformity). As a result, the operation controller 9 can accurately determine the polishing end point of the substrate W.

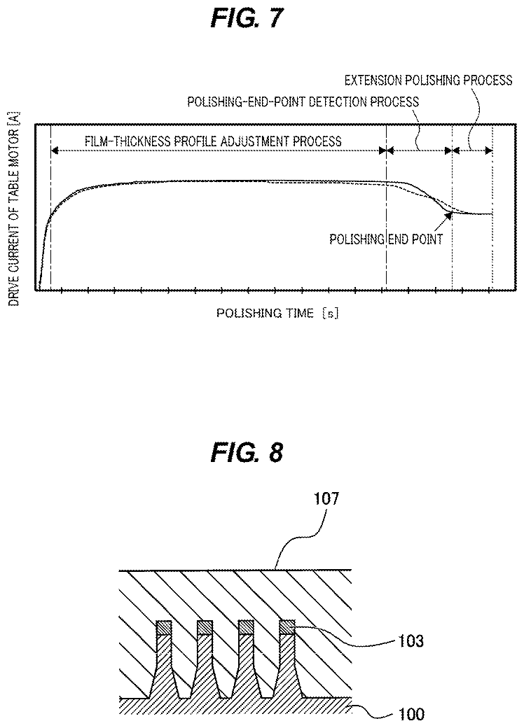

FIG. 7 is a diagram showing the measured value of the drive current of the table motor 6 in each polishing process. A curve represented by a dotted line shows the measured value of the drive current of the table motor 6 when the polishing-end-point detection process is performed without executing the film-thickness profile adjustment process, and a curve represented by a solid line shows the measured value of the drive current of the table motor 6 when the polishing end point detection process is performed after the film-thickness profile adjustment process is performed. As shown in FIG. 7, when the film-thickness profile adjustment process is not performed (indicated by the dotted line), the measured value of the drive current of the table motor 6 continues to decrease even after the polishing end point (at which the dielectric film 107 on the stopper layer 103 is removed) has elapsed. In contrast, when the polishing-end-point detection process is performed after the film-thickness profile adjustment process is performed (shown by the solid line), the measured value of the drive current of the table motor 6 becomes constant when the dielectric film 107 on the stopper layer 103 is removed. Therefore, the operation controller 9 can accurately determine the polishing end point of the substrate W at which the measured value of the drive current of the table motor 6 becomes constant.

As the polishing end point of the substrate W approaches, the thickness of the dielectric film 107 on the stopper layer 103 becomes extremely small. When the thickness of the dielectric film 107 is reduced to near the limit of the measurement accuracy of the film-thickness measuring device 40, the film thickness measuring accuracy of the film-thickness measuring device 40 is lowered. As a result, it may be difficult to determine the polishing end point of the substrate W based only on the film thickness measured by the film-thickness measuring device 40. According to this embodiment, the polishing apparatus can accurately determine the polishing end point of the substrate W by the combination of the film-thickness profile adjustment process and the polishing-end-point detection process.

In one embodiment, the polishing apparatus may perform an initial polishing process prior to the film-thickness profile adjustment process. The initial polishing process includes measuring the torque for rotating the polishing table 3 during polishing of the substrate W, and determining an initial polishing end point of the substrate W based on the torque. Details of the initial polishing process, which will not be particularly described, are the same as the polishing-end-point detection processes described with reference to the steps 6 to 8, and repetitive descriptions thereof will be omitted. In the initial polishing process, the operation controller 9 compares the measured value of the torque (or the rate of change in the torque) with a preset initial torque threshold value (or a preset initial rate-of-change threshold value). When the measured torque value (or the rate of change in the torque) has reached the initial torque threshold value (or the initial rate-of-change threshold value), the operation controller 9 determines the initial polishing end point at which the measured torque value has reached the initial torque threshold value.

FIG. 8 is a diagram showing the substrate W that has been polished to the initial polishing end point. The initial polishing end point is a point in time at which the surface of the dielectric film 107 becomes flat as a result of polishing of the raised portions of the dielectric film 107 having the stepped surface. FIG. 8 shows a state between the state of the substrate W shown in FIG. 5A and the state of the substrate W shown in FIG. 5B. As shown in FIGS. 5A to 5C, when the underlying silicon layer 100 has an uneven stepped surface, the upper dielectric film 107 may have the stepped surface as shown in FIG. 5A. When the dielectric film 107 has the stepped surface, only the raised portions of the surface of the dielectric film 107 contact the polishing pad 2. Therefore, a contact area of the dielectric film 107 and the polishing pad 2 when the dielectric film 107 has the stepped surface is smaller than a contact area when the dielectric film 107 does not have the stepped surface (i.e., when the surface of the dielectric film 107 is flat). As a result, the frictional force acting between the substrate W and the polishing pad 2 (or the torque for rotating the polishing table 3) when the dielectric film 107 has the stepped surface is different from the frictional force (or the torque) when the dielectric film 107 does not have the stepped surface. Therefore, the operation controller 9 can determine the initial polishing end point based on the change in the measured value of torque (or the rate of change in the torque). The initial torque threshold value (or the initial rate-of-change threshold value) is predetermined based on experiments or past polishing results.

When the dielectric film 107 has the stepped surface, the accuracy of measuring the film thickness of the dielectric film 107 by the film-thickness measuring device 40 may be lowered. By performing the initial polishing process before the film-thickness profile adjustment process as described above, the film-thickness measuring device 40 can accurately measure the thickness of the dielectric film 107.

All of the initial polishing process, the film-thickness profile adjustment process, the polishing-end-point detection process, and the extension polishing process discussed above are performed by the polishing apparatus shown in FIG. 1. Specifically, the initial polishing process, the film-thickness profile adjustment process, the polishing-end-point detection process, and the extension polishing process are sequentially performed while the substrate W is pressed against the polishing pad 2 on the same polishing table 3 by the polishing head 1. Since these multiple processes are performed while the substrate W is in contact with the polishing pad 2 on the same polishing table 3, a throughput is improved.

The operation controller 9 performs each of the above steps according to the instructions contained in the programs stored in the memory 9a. The programs for causing the operation controller 9 to perform each of the above steps are stored in a computer-readable storage medium which is a non-transitory tangible object, and is provided to the operation controller 9 via the storage medium. Alternatively, the programs may be input to the operation controller 9 via a communication network, such as the Internet or a local area network.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a polishing method and a polishing apparatus for polishing a substrate, such as a wafer. The present invention is further applicable to a computer-readable storage medium storing a program for causing the polishing apparatus to perform the polishing method.

### REFERENCE SIGNS LIST

1 polishing head
2 polishing pad
2a polishing surface
3 polishing table
5 polishing-liquid supply nozzle
6 table motor
7 optical sensor head
8 torque measuring device
9 operation controller
10 head shaft
21 head body
25 rotary joint
40 film-thickness measuring device (or optical film-thickness measuring device
44 light source
47 spectrometer
49 processing system
60 retainer ring
60a lower surface
62 drive ring
65 elastic membrane
70,71,72,73 pressure chamber
80 retainer-ring pressing device
81 piston
82 rolling diaphragm
83 retainer-ring pressure chamber
100 silicon layer
103 stopper layer
107 dielectric film
R1,R2,R3,R4,R5 pressure regulator

1. A polishing method comprising:
rotating a polishing table that supports a polishing pad; and
polishing a substrate by pressing the substrate against a polishing surface of the polishing pad by a polishing head, the substrate having a multilayered structure including a dielectric film and a stopper layer formed under the dielectric film,
wherein polishing the substrate includes a film-thickness profile adjustment process and a polishing-end-point detection process performed after the film-thickness profile adjustment process,
the film-thickness profile adjustment process includes measuring a plurality of film thicknesses at a plurality of measurement points on the substrate, adjusting pressing forces on the substrate against the polishing surface based on the plurality of film thicknesses, and determining a point in time at which a film-thickness index value has reached a film-thickness threshold value, the film-thickness index value being determined from at least one of the plurality of film thicknesses, and
the polishing-end-point detection process includes measuring a torque for rotating the polishing table and determining a polishing end point of the substrate based on the torque.

2. The polishing method according to claim 1, wherein adjusting the pressing forces includes adjusting the pressing forces on the substrate against the polishing surface based on the plurality of film thicknesses such that a surface, to be polished, of the substrate becomes flat.

3. The polishing method according to claim 1, wherein measuring the plurality of film thicknesses includes irradiating the substrate with light, generating a plurality of spectra of reflected light from the plurality of measurement points on the substrate, and determining the plurality of film thicknesses based on the plurality of spectra.

4. The polishing method according to claim 1, wherein polishing the substrate further includes an initial polishing process performed before the film-thickness profile adjustment process, the initial polishing process including measuring a torque for rotating the polishing table and determining an initial polishing end point based on the torque.

5. A computer-readable storage medium storing a program for causing a computer to perform:
instructing a table motor to rotate a polishing table that supports a polishing pad;
instructing a plurality of pressure regulators to adjust pressing forces on a substrate against a polishing surface of the polishing pad based on a plurality of film thicknesses at a plurality of measurement points on the substrate when a polishing head is pressing the substrate against the polishing surface to polish the substrate, the polishing head having a plurality of pressure chambers coupled to the plurality of pressure regulators;
determining a point in time at which a film-thickness index value has reached a film-thickness threshold value, the film-thickness index value being determined from at least one of the plurality of film thicknesses; and
determining a polishing end point of the substrate based on a torque for rotating the polishing table after determination of the point in time at which the film-thickness index value has reached the film-thickness threshold value.

6. The computer-readable storage medium according to claim 5, wherein instructing the plurality of pressure regulators to adjust the pressing forces on the substrate against the polishing surface comprises instructing the plurality of pressure regulators to adjust the pressing forces on the substrate against the polishing surface based on the plurality of film thicknesses at the plurality of measurement points such that a surface, to be polished, of the substrate becomes flat.

7. The computer-readable storage medium according to claim 5, wherein the program is configured to cause the computer to further perform determining an initial polishing end point based on a torque for rotating the polishing table when the substrate is being polished and before the plurality of pressure regulators adjust the pressing forces on the substrate against the polishing surface.

8. A polishing apparatus for polishing a substrate having a multilayered structure including a dielectric film and a stopper layer formed under the dielectric film, comprising:
a polishing table configured to support a polishing pad;
a table motor configured to rotate the polishing table;
a polishing head having a plurality of pressure chambers for pressing the substrate against a polishing surface of the polishing pad;
a film-thickness measuring device configured to measure a plurality of film thicknesses at a plurality of measurement points on the substrate;
a plurality of pressure regulators coupled to the plurality of pressure chambers;
a torque measuring device configured to measure a torque for rotating the polishing table; and
an operation controller configured to control operations of the polishing apparatus,
wherein the operation controller is configured to:
perform a film-thickness profile adjustment process of instructing the plurality of pressure regulators to adjust pressing forces on the substrate against the polishing surface based on the plurality of film thicknesses during polishing of the substrate, and determining a point in time at which a film-thickness index value has reached a film-thickness threshold value, the film-thickness index value being determined from at least one of the plurality of film thicknesses; and
determine a polishing end point of the substrate based on the torque during polishing of the substrate and after the film-thickness profile adjustment process.

9. The polishing apparatus according to claim 8, wherein the operation controller is configured to instruct the plurality of pressure regulators to adjust the pressing forces on the substrate against the polishing surface based on the plurality of film thicknesses such that a surface, to be polished, of the substrate becomes flat.

10. The polishing apparatus according to claim 8, wherein the film-thickness measuring device is an optical film-thickness measuring device configured to measure a film thickness of the substrate based on a spectrum of reflected light from the substrate.

11. The polishing apparatus according to claim 8, wherein the operation controller is configured to determine an initial polishing end point based on the torque for rotating the polishing table during polishing of the substrate and before the film-thickness profile adjustment process.
